(19) United States
(12) Patent Application Publication
(10) Pub. No.: US 2026/0196861 A1
(43) Pub. Date: Jul. 9, 2026

(54) ELECTRONIC DEVICE AND BATTERY MANAGEMENT METHOD THEREOF

(71) Applicant: ASUSTeK COMPUTER INC., Taipei City (TW)

(72) Inventors: Jun-Fu Chen, Taipei City (TW); Ming Hung Yao, Taipei City (TW); Bo-Chao Jhan, Taipei City (TW); Sheng-Chung Wang, Taipei City (TW)

(73) Assignee: ASUSTeK COMPUTER INC., Taipei City (TW)

(21) Appl. No.: 19/366,394

(22) Filed: Oct. 22, 2025

(30) Foreign Application Priority Data
Jan. 3, 2025 (TW) 114100243

(51) Int. Cl. H02J 7/90; G01R 31/388; H02J 7/80

(52) U.S. Cl. CPC H02J 7/971; G01R 31/388; H02J 7/80

(57) ABSTRACT

An electronic device and a battery management method thereof are provided. The method includes: when an auto shipping mode function is turned on and a battery module is in a sleep mode, continuously accumulating a storage time count value; and when the storage time count value accumulates to greater than a time threshold, determining whether to put the battery module into a shutdown mode according to a current battery voltage of the battery module.

### CROSS-REFERENCE TO RELATED APPLICATION

This application claims the priority benefit of Taiwan application serial no. 114100243, filed on January 3, 2025. The entirety of the above-mentioned patent application is hereby incorporated by reference herein and made a part of this specification.

### BACKGROUND

### Technical Field

The disclosure relates to an electronic device capable of extending a storage time of a battery module and a battery management method adopted thereby.

### Description of Related Art

Nowadays, handheld electronic products (such as laptops, mobile phones, digital cameras, or tablet computers) are typically powered by a power adapter (e.g., an AC adapter) or a battery module. Powering the system motherboard through a battery module allows users to perform operations anytime and anywhere. However, educational institutions or organizational units may not immediately use the electronic products after purchase due to certain factors, resulting in the system of the electronic product being in a storage state (a state of not being used for a long time). In the storage state, due to self-consumption of power by the system motherboard and the battery module, the storage time of the battery module will be reduced. Moreover, when energy is excessively consumed, it may further lead the battery module to enter a permanent fail (PF) state.

### SUMMARY

The disclosure provides a battery management method adapted for an electronic device including a battery module. The method is described below. When an auto shipping mode function is turned on and the battery module is in a sleep mode, a storage time count value is continuously accumulated. When the storage time count value accumulates to greater than a time threshold, it is determined whether to put the battery module into a shutdown mode according to a current battery voltage of the battery module.

The disclosure also provides an electronic device including a battery module and a controller. The battery module includes battery cells and a control circuit. The control circuit is coupled to the battery cells and configured to continuously accumulate a storage time count value when an auto shipping mode function is turned on and the battery module is in a sleep mode. The controller is coupled to the battery module and configured to set a parameter used by the battery module. When the storage time count value accumulates to be greater than a time threshold, the control circuit determines whether to put the battery module into a shutdown mode according to a current battery voltage of the battery module.

Based on the above, the electronic device and the battery management method thereof of the disclosure may automatically put the battery module into a shutdown mode in a relax mode (e.g., the S5 mode specified by the advanced configuration and power interface, ACPI). As a result, this may extend the storage time of the battery module and avoid the battery module entering a permanent fail state.

In order to make the aforementioned features and advantages of the disclosure more comprehensible, embodiments accompanied with figures are described in detail below.

### BRIEF DESCRIPTION OF THE DRAWINGS

FIG. 1 is a block schematic view of an electronic device according to an embodiment of the disclosure.

FIG. 2 is a flowchart illustrating the steps of a battery management method according to an embodiment of the disclosure.

FIG. 3 is a flowchart illustrating the steps of a battery management method according to an embodiment of the disclosure.

### DESCRIPTION OF THE EMBODIMENTS

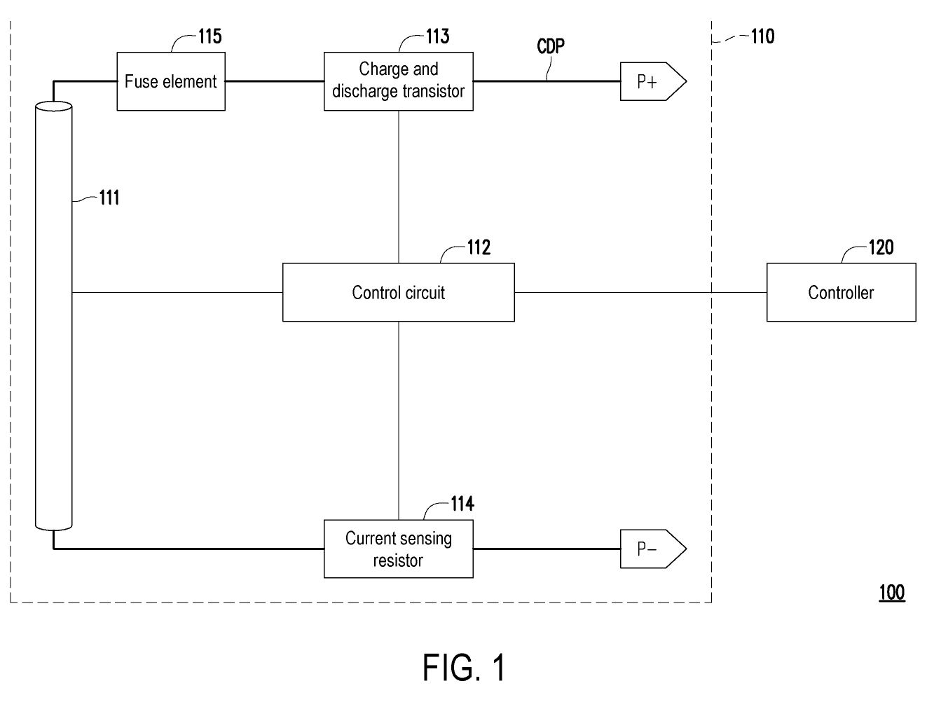

Referring to FIG. 1, in the embodiment, the electronic device 100 is a handheld electronic product such as a laptop computer, mobile phone, digital camera, or tablet computer. The electronic device 100 includes a battery module 110 and a controller 120.

The battery module 110 may supply power to the electronic device 100 through a positive terminal P+ and a negative terminal P- of a charge and discharge path CDP. In one embodiment, the battery module 110 is embedded or external, and as shown in FIG. 1, includes battery cells 111, a control circuit 112, a charge and discharge transistor 113, a current sensing resistor 114, and a fuse element 115. In one embodiment, the battery cells 111 is composed of a single or multiple lithium battery cells (individual battery cells), which may be used to store electrical energy.

The charge and discharge transistor 113 is disposed on the charge and discharge path CDP, and may be used to connect or disconnect the charge and discharge path CDP.

The current sensing resistor 114 is disposed on the charge and discharge path CDP, and may be used to enable the control circuit 112 to detect the charge and discharge current flowing through the charge and discharge path CDP.

The fuse element 115 is disposed on the charge and discharge path CDP and may serve as a hardware protection mechanism. When the voltage of the battery cells 111 is too high (abnormal), the fuse element 115 may provide one or multiple stages of protection.

The control circuit 112 is coupled to the battery cells 111, the charge and discharge transistor 113, and the current sensing resistor 114, and may be implemented by a battery gauge IC or a microcontroller. The control circuit 112 may monitor information such as the electrical energy stored in the battery cells 111, the battery voltage, and the charge and discharge current, and report back to the controller 120. Furthermore, the control circuit 112 includes a counter or has a counting function, which may be used to accumulate count values (storage time count values).

The controller 120 is coupled to the battery module 110. In one embodiment, the controller 120 is an embedded controller (EC) or a microcontroller that communicates with the control circuit 112 through a communication protocol, and the controller 120 also sets parameters (e.g., time threshold and voltage threshold) used by the battery module 110. The communication protocol is, for example, a system management bus (SMBus) or an inter-integrated circuit (I²C), but the embodiment is not limited thereto.

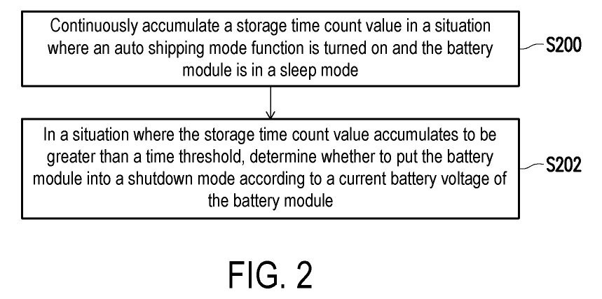

The battery management method of the disclosure executes the algorithm related to the auto shipping mode function, thereby enabling the battery module 110 to enter the shutdown mode. Referring to both FIG. 1 and FIG. 2, the battery management method of this embodiment is adapted for the electronic device 100 in FIG. 1, and its steps are described as follows.

First, in step S200, the control circuit 112 continuously accumulates a storage time count value when an auto shipping mode function is turned on and the battery module 110 is in a sleep mode. Specifically, the control circuit 112 may check the bit value of the auto shipping mode enabling bit (CVSHIP_EN) written in its internal memory. In one embodiment, the auto shipping mode enabling bit is written to the control circuit 112 through a power management related application. When the bit value of the auto shipping mode enabling bit is 1, it indicates that the auto shipping mode function is turned on. When the bit value of the auto shipping mode enabling bit is 0, it indicates that the auto shipping mode function is not turned on. If the auto shipping mode function is turned on and the battery module 110 is in the sleep mode, the control circuit 112 starts to continuously accumulate the storage time count value.

Next, in step S202, when the storage time count value accumulates to be greater than a time threshold, the control circuit 112 determines whether to put the battery module 110 into a shutdown mode according to a current battery voltage of the battery module 110. For example, when the storage time count value accumulates to be greater than the time threshold, the control circuit 112 may judge whether the current battery voltage of the battery module 110 is less than the voltage threshold. If the current battery voltage is less than the voltage threshold, the control circuit 112 puts the battery module 110 into the shutdown mode, thereby extending the storage time of the battery module 110.

The voltage threshold in this embodiment may correspond to the storage voltage of the battery module 110. The controller 120 may set the time threshold and the voltage threshold according to at least one of user group, usage scenario, and user habit. For example, the time threshold and the voltage threshold are stored in the memory within the control circuit 112, with a record length of one word, which is divided into a high byte (bits 15 to 8) and a low byte (bits 7 to 0). The value of the high byte multiplied by 32 is the voltage threshold (in millivolts (mV)). The value of the low byte is the time threshold (in days). In addition, when the value of the low byte is set to "00000000", 0 days indicates that the time threshold is 5 minutes. The controller 120 may analyze the user group, usage scenario, or user habit of the electronic device 100 through artificial intelligence (AI) learning, and use the command character instruction 0x93 to flexibly adjust the time threshold and the voltage threshold recorded in the control circuit 112 based on the analysis results, thereby optimizing the system to put the battery module 110 into the shutdown mode automatically to extend the storage time in different usage regions or environments, further ensuring that the battery module 110 is effective and not easily damaged.

In one embodiment, when the electronic device 100 is powered off (i.e., the system enters the S5 mode as defined by the advanced configuration and power interface (ACPI)), the control circuit 112 judges whether the auto shipping mode function is turned on and whether the battery module 110 is in the sleep mode, so as to execute the battery management method of this embodiment (that is, the steps shown in FIG. 2) in the situation where the auto shipping mode function is turned on and the battery module 110 is in sleep mode.

Moreover, when the battery module 110 in the shutdown mode is woken up (e.g., woken up by the system to start charging and discharging), the control circuit 112 changes the time threshold and the voltage threshold back to their corresponding default values and resets the storage time count value (e.g., resets it to 0).

Incidentally, when the battery module 110 is in the sleep mode, the charge and discharge transistor 113 remains turned on. However, when the battery module 110 enters the shutdown mode, the control circuit 112 disconnects the charge and discharge transistor 113 to prohibit any charging or discharging from occurring.

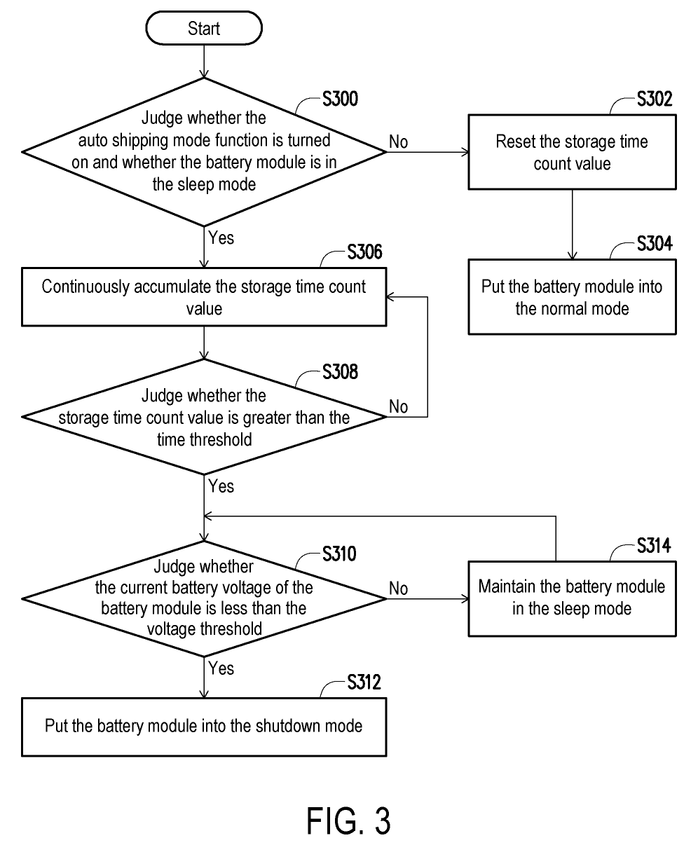

The following is another embodiment to illustrate the implementation details of the battery management method of the disclosure. Referring to FIG. 1 and FIG. 3 simultaneously, the battery management method of this embodiment is executed, for example, when the electronic device 100 is powered off (i.e., the system enters the S5 mode as defined by the Advanced Configuration and Power Interface (ACPI)), and is adapted for the electronic device 100 in FIG. 1. The steps are described as follows.

First, in step S300, the control circuit 112 judges whether the auto shipping mode function is turned on and whether the battery module 110 is in the sleep mode.

In the situation where the auto shipping mode function is not turned on or the battery module 110 is not in the sleep mode, in step S302, the control circuit 112 resets the storage time count value. Then, in step S304, the control circuit 112 puts the battery module 110 into the normal mode where charging and discharging is performed.

On the other hand, in the situation where the auto shipping mode function is turned on and the battery module 110 is in the sleep mode, in step S306, the control circuit 112 starts to continuously accumulate the storage time count value. Then, in step S308, the control circuit 112 judges whether the accumulated storage time count value is greater than the time threshold.

If yes, then proceed to step S310. If no, then return to step S306, thereby allowing the control circuit 112 to repeatedly judge whether the storage time count value is greater than the time threshold while continuously accumulating the storage time count value until the storage time count value accumulates to be greater than the time threshold. In one embodiment, before the storage time count value accumulates to be greater than the time threshold, once the battery module 110 performs charging or discharging, the control circuit 112 resets the storage time count value.

In step S310, the control circuit 112 judges whether the current battery voltage of the battery module 110 is less than the voltage threshold. When the current battery voltage is less than the voltage threshold, in step S312, the control circuit 112 puts the battery module 110 into the shutdown mode.

When the current battery voltage is not less than the voltage threshold, in step S314, the control circuit 112 maintains the battery module 110 in the sleep mode, then returns to step S310 to repeatedly judge whether the current battery voltage of the battery module 110 is less than the voltage threshold until waiting for the current battery voltage to drop to be less than the voltage threshold.

In summary, the electronic device and the battery management method thereof of the disclosure may automatically put the battery module into the shutdown mode in a relax mode, and allow the controller to flexibly adjust the parameters used by the battery module using command character instructions, without the need to send it back to the battery manufacturer for configuration. As a result, this may extend the storage time of the battery module, avoid the battery module entering a permanent fail state, and improve the convenience of use.

What is claimed is:

1. A battery management method, adapted for an electronic device comprising a battery module, the battery management method comprising:
accumulating a storage time count value continuously when an auto shipping mode function is turned on and the battery module is in a sleep mode; and
determining whether to put the battery module into a shutdown mode according to a current battery voltage of the battery module when the storage time count value accumulates to greater than a time threshold.

2. The battery management method according to claim 1, further comprising:
judging whether the auto shipping mode function is turned on and whether the battery module is in the sleep mode when the electronic device is powered off.

3. The battery management method according to claim 1, further comprising:
resetting the storage time count value, then putting the battery module into a normal mode when the auto shipping mode function is not turned on or the battery module is not in the sleep mode.

4. The battery management method according to claim 1, further comprising:
judging whether the storage time count value is greater than the time threshold; and
when the storage time count value is not greater than the time threshold, repeatedly judging the storage time count value while continuously accumulating the storage time count value until the storage time count value accumulates to greater than the time threshold.

5. The battery management method according to claim 1, wherein determining whether to put the battery module into the shutdown mode according to the current battery voltage of the battery module comprises:
judging whether the current battery voltage of the battery module is less than a voltage threshold;
putting the battery module into the shutdown mode when the current battery voltage is less than the voltage threshold; and
maintaining the battery module in the sleep mode and repeatedly judging the current battery voltage of the battery module until the current battery voltage is less than the voltage threshold when the current battery voltage is not less than the voltage threshold.

6. The battery management method according to claim 5, further comprising:
setting the time threshold and the voltage threshold according to at least one of user group, usage scenario, and user habit.

7. The battery management method according to claim 5, further comprising:
changing the time threshold and the voltage threshold back to corresponding preset values, respectively when the battery module in the shutdown mode is woken up.

8. The battery management method according to claim 1, wherein the battery module further comprises a charge and discharge transistor disposed on a charge and discharge path, the battery management method further comprising:
disconnecting the charge and discharge transistor when the battery module enters the shutdown mode.

9. The battery management method according to claim 1, further comprising:
resetting the storage time count value when the battery module in the shutdown mode is woken up.

10. An electronic device, comprising:
a battery module, comprising battery cells and a control circuit, the control circuit coupled to the battery cells, and the control circuit configured to continuously accumulate a storage time count value when an auto shipping mode function is turned on and the battery module is in a sleep mode; and
a controller, coupled to the battery module and configured to set a parameter used by the battery module,
wherein when the storage time count value accumulates to be greater than a time threshold, the control circuit determines whether to put the battery module into a shutdown mode according to a current battery voltage of the battery module.

11. The electronic device according to claim 10, wherein when the electronic device is powered off, the control circuit judges whether the auto shipping mode function is turned on and whether the battery module is in the sleep mode.

12. The electronic device according to claim 10, wherein when the auto shipping mode function is not turned on or the battery module is not in the sleep mode, the control circuit resets the storage time count value, then puts the battery module into a normal mode.

13. The electronic device according to claim 10, wherein the control circuit judges whether the storage time count value is greater than the time threshold, and
when the storage time count value is not greater than the time threshold, the control circuit repeatedly judges the storage time count value while continuously accumulating the storage time count value until the storage time count value accumulates to greater than the time threshold.

14. The electronic device according to claim 10, wherein the control circuit judges whether the current battery voltage of the battery module is less than a voltage threshold,
when the current battery voltage is less than the voltage threshold, the control circuit puts the battery module into the shutdown mode, and
when the current battery voltage is not less than the voltage threshold, the control circuit maintains the battery module in the sleep mode and repeatedly judges the current battery voltage of the battery module until the current battery voltage is less than the voltage threshold.

15. The electronic device according to claim 14, wherein the controller sets the time threshold and the voltage threshold according to at least one of user group, usage scenario, and user habit.

16. The electronic device according to claim 14, wherein when the battery module in the shutdown mode is woken up, the control circuit changes the time threshold and the voltage threshold back to corresponding preset values, respectively.

17. The electronic device according to claim 10, wherein the battery module further comprises a charge and discharge transistor, a current sensing resistor, and a fuse element disposed on a charge and discharge path, the control circuit is coupled to the charge and discharge transistor and the current sensing resistor, and
when the battery module enters the shutdown mode, the control circuit disconnects the charge and discharge transistor.

18. The electronic device according to claim 10, wherein when the battery module in the shutdown mode is woken up, the control circuit resets the storage time count value.
